(19) United States
(12) Patent Application Publication
(10) Pub. No.: US 2005/0282338 A1
(43) Pub. Date: Dec. 22, 2005

(54) Methods of forming gate patterns using isotropic etching of gate insulating layers

(76) Inventors: Jong-Ryeol Yoo, Gyeonggi (KR); Gil-Heyun Choi, Gyeonggi-do (KR); Chang-Won Lee, Gyeonggi-do (KR); Byung-Hak Lee, Gyeonggi-do (KR); Hee-Sook Park, Seoul (KR); Dong-Chan Lim, Gyeonggi-do (KR); Sun-Pil Youn, Seoul (KR); Woong-Hee Sohn, Seoul (KR)

Correspondence Address: MYERS BIGEL SIBLEY & SAJOVEC, PO BOX 37428, RALEIGH, NC, 27627, US

(21) Appl. No.: 11/153,653

(22) Filed: Jun. 15, 2005

(30) Foreign Application Priority Data
Jun. 17, 2004 (KR) 2004-45056
Jan. 7, 2005 (KR) 2005-01779

(51) Int. Cl. H01L 21/336; H01L 21/8234; H01L 21/4763; H01L 21/302; H01L 21/461

(52) U.S. Cl. 438/257; 438/723

(57) ABSTRACT

A method for forming a gate pattern of a semiconductor device can include isotropically etching a gate insulating layer located between a gate conductive layer pattern and a substrate to recess an exposed side wall of the gate insulating layer pattern beyond a lower corner of the gate conductive layer pattern to form an undercut region. The gate conductive layer pattern can be treated to round off the lower corner.

### CROSS-REFERENCE TO RELATED APPLICATIONS

This U.S. non-provisional patent application claims priority under 35 U.S.C. § 119 of Korean Patent Applications 2004-45056 filed on Jun. 17, 2004 and 2005-01779 filed on Jan. 7, 2005, the entire contents of which are hereby incorporated by reference.

### FIELD OF THE INVENTION

The present invention relates to methods of forming semiconductor devices, and more particularly, to methods of forming gate patterns in semiconductor devices.

### BACKGROUND

Metal-Oxide-Semiconductor (MOS) transistors typically include a gate electrode disposed on a semiconductor substrate and source/drain regions in the semiconductor substrate on both sides of the gate electrode. A gate insulating layer can be located between the gate electrode and the semiconductor substrate.

FIGS. 1 and 2 are process cross-sectional views illustrating a general method of manufacturing a conventional MOS transistor. Referring to FIG. 1, device isolation layers 20 defining an active region can be formed in a predetermined region of the semiconductor substrate 10. Next, a gate insulating layer 30 can be formed on a top surface of the active region. The gate insulating layer 30 can be a silicon oxide layer formed using a thermal oxidation process.

A lower gate conductive layer 40, an upper gate conductive layer 50 and a capping layer 60 can be sequentially formed on a surface of a semiconductor substrate including on the gate insulating layer 30. In general, the lower gate conductive layer 40 can be formed of polycrystalline silicon, and the upper gate conductive layer 50 can be formed of a conductive material having a lower resistivity than polycrystalline silicon, such as a metal.

Referring to FIG. 2, the capping layer 60, the upper gate conductive layer 50 and the lower gate conductive layer 40 can be sequentially patterned to form a gate pattern 99 on the gate insulating layer 30 in the active region. The gate pattern 99, therefore, can include a lower gate pattern 45, an upper gate pattern 55 and a capping pattern 65 as shown. The gate pattern 99 can be formed by isotropically etching using a plasma, which may damage the sidewalls of the lower gate pattern 45. An oxidation process can be used to repair etching damage, which forms a silicon oxide layer 70 on the side walls of the lower gate pattern 45.

As shown in FIG. 2, the lower gate pattern 45 can include a lower edge A that has an angular shape despite the formation of the oxide layer 70. The shape of the lower edge A may give rise to relatively concentrated electric fields thereat in response to a voltage applied to the gate pattern 99. These relatively concentrated electric fields may cause increased leakage currents or gate induced drain leakage (GIDL).

### SUMMARY

Embodiments according to the invention can provide methods of forming gate patterns using isotropic etching of gate insulating layers. Pursuant to these embodiments, a method for forming a gate pattern of a semiconductor device can include isotropically etching a gate insulating layer located between a gate conductive layer pattern and a substrate to recess an exposed side wall of the gate insulating layer pattern beyond a lower corner of the gate conductive layer pattern to form an undercut region. The gate conductive layer pattern can be treated to round off the lower corner.

In some embodiments according to the invention, treating the semiconductor includes annealing the gate conductive layer pattern using a process gas of hydrogen. In some embodiments according to the invention, annealing includes using hydrogen H₂ gas and/or hydrogen H atoms, or using H₂ gas and/or H atoms with O₂ gas, H₂O, N₂ gas, Ar gas and/or He gas.

In some embodiments according to the invention, the method further includes forming a silicon oxide layer on a side wall of the gate conductive layer pattern. In some embodiments according to the invention, forming a silicon oxide layer includes dry oxidation, wet oxidation or a low temperature radical oxidation. In some embodiments according to the invention, treating includes oxidizing to forming a silicon oxide layer on a side wall of the gate conductive layer pattern.

In some embodiments according to the invention, oxidizing includes oxidizing and annealing using a process gas comprising H₂ gas and/or H atoms, or H₂ gas and/or H atoms with O₂ gas, H₂O, N₂ gas, Ar gas and/or He gas. In some embodiments according to the invention, the gate conductive layer pattern is polycrystalline silicon. In some embodiments according to the invention, the method further includes wet-etching the gate insulating layer using the gate conductive layer pattern as an etch mask, wherein the wet-etching is performed using an etching solution having an etch selectivity with respect to the gate conductive layer pattern.

In some embodiments according to the invention, the gate insulating layer is a silicon oxide SiO₂ layer, a hafnium oxide HfO₂ layer, an aluminum oxide Al₂O₃ layer, a zirconium oxide ZrO₂ layer, a tantalum oxide Ta₂O₅ layer, a titanium oxide TiO₂ layer, a lanthanum oxide La₂O₃ layer and/or a hafnium silicon oxide HfₓSi₁₋ₓO₂ layer.

In some embodiments according to the invention, a gate insulating layer is formed on a semiconductor substrate. A gate pattern is formed exposing a top surface of a predetermined region of the gate insulating layer, the gate pattern includes a lower gate pattern, a gate interlayer insulating layer pattern, and an upper gate pattern. The gate insulating layer is isotropically etched to recess an exposed side wall of the gate insulating layer beyond a lower corner of the lower gate pattern to form an undercut region therebeneath. The gate pattern is treated to round off the lower corner of the lower gate pattern. A side wall of the lower gate pattern, a portion of undercut region, and a side wall of the gate interlayer insulating layer pattern are oxidized. A side wall of the upper gate pattern above the gate interlayer insulating layer pattern is oxidized also.

### BRIEF DESCRIPTION OF THE DRAWINGS

FIGS. 1 and 2 are cross-sectional views illustrating a method for forming a conventional gate pattern of a MOS transistor.

FIGS. 3 to 6 are cross-sectional views illustrating forming MOS transistors including gate patterns in some embodiments according to the present invention.

FIGS. 7 to 10 are cross-sectional views illustrating forming MOS transistors including gate patterns in some embodiments according to the present invention.

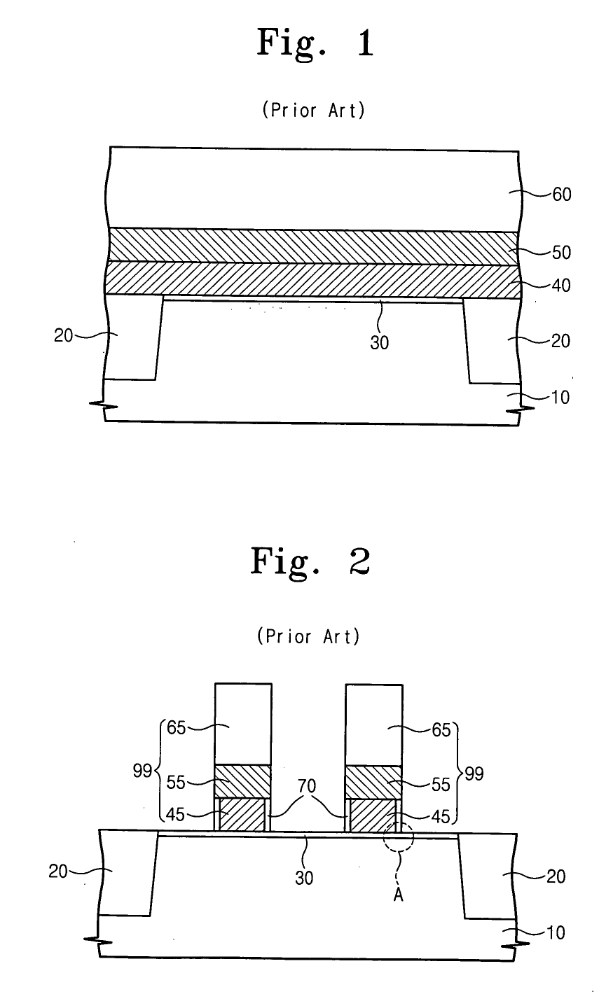

### DESCRIPTION OF EMBODIMENTS ACCORDING TO THE INVENTION

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower”, “bottom”, “upper”, “top”, “beneath”, “above”, and the like are used herein to describe one element's relationship to another elements as illustrated in the Figures. It will be understood that relative terms are intended to encompass different orientations of the subject in the figures in addition to the orientation depicted in the Figures. For example, if the subject in the Figures is turned over, elements described as being on the “lower” side of or “below” other elements would then be oriented on “upper” sides of (or “above”) the other elements. The. exemplary term “lower”, can therefore, encompasses both an orientation of “lower” and “upper,” depending of the particular orientation of the figure. Similarly, if the subject in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

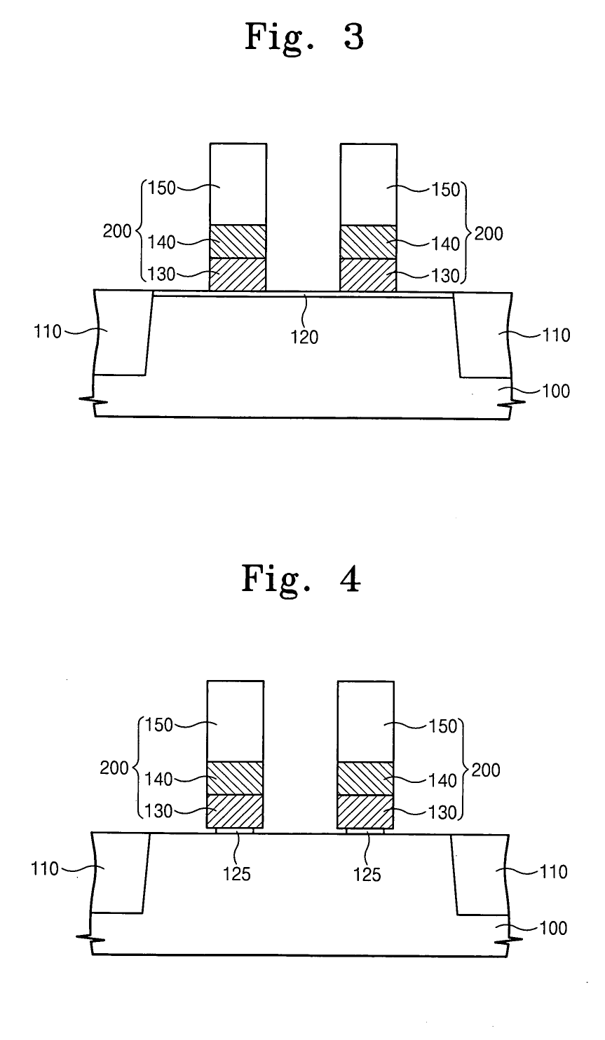

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature. FIGS. 3 to 6 are cross-sectional views showing formation of a MOS transistor in some embodiments according to the present invention. Referring to FIG. 3, device isolation layers 10 defining an active region are formed in a predetermined region of a semiconductor substrate 100. In some embodiments according to the present invention, the device isolation layer 110 may be formed using a shallow trench isolation STI process. The shallow trench isolation process can include forming trench mask patterns (not shown) on the semiconductor substrate 100 and anisotropically-etching the semiconductor substrate 100 using the trench mask patterns as an etch mask. The trench regions may be formed to a predetermined depth and can be filled with an insulating layer. The insulating layer in the trenches is planarization-etched until the trench mask patterns are expose to form the isolation layers 110 and the trench mask patterns can be removed.

A gate insulating layer 120 is formed on a top surface of the active region. In some embodiments according to the invention, the gate insulating layer 120 is a silicon oxide layer formed using a thermal oxidation process. In some embodiments according to the invention, the gate insulating layer is a high-k dielectric layer such as a hafnium oxide (HfO₂) layer, an aluminum oxide (Al₂O₃) layer, a zirconium oxide (ZrO₂) layer, a tantalum oxide (Ta₂O₅) layer, a titanium oxide (TiO₂) layer, a lanthanum oxide (La₂O₃) layer or a hafnium silicon oxide (HfₓSi₁₋ₓO₂) layer.

A lower gate conductive layer, an upper gate conductive layer and a capping layer are formed on the gate insulating layer 120. In some embodiments according to the invention, the lower gate conductive layer is formed of polycrystalline silicon, and the upper gate conductive layer is formed of a conductive material having a lower resistivity than polycrystalline silicon, for example, tungsten (W) or tungsten silicide (WSiₓ). In some embodiments according to the invention, the capping layer is a silicon oxide layer, a silicon nitride layer and/or a silicon oxide nitride layer.

The capping layer, the gate conductive layer and the lower gate conductive layer are sequentially patterned to form a gate pattern 200 crossing over the active region on the gate insulating layer 120. The gate pattern 200 includes a lower gate pattern 130, an upper gate pattern 140 and a capping pattern 150, which are sequentially stacked on the gate insulating layer 120. In some embodiments according to the invention, the lower gate pattern 130 and the upper gate pattern 140 may be formed by anisotropic etching using the capping pattern 150 as an etch mask.

Referring to FIG. 4, the portion of the gate insulating layer 120 that is exposed (i.e., the portion not beneath the gate pattern 200) is isotropically etched. In some embodiments according to the invention, the etching is performed using a solution that is selective relative to the gate insulating layer 120. In other words, solution may etch the gate insulating layer 120 and not etch the elements of the gate pattern 200, the device isolation layer 10, and the semiconductor substrate 100. If the gate insulating layer 120 is a silicon oxide layer, the etching can be a selective wet-etch of the gate insulating layer 120 using an etching solution including hydrofluoric HF acid.

According to the etching, a gate insulating layer pattern 125 is formed beneath the gate pattern 200 and exposes a top surface of the semiconductor substrate 100. The gate insulating layer pattern 125 corresponds to an undercut region formed between the lower gate pattern 130 and the semiconductor substrate 100. The gate insulating layer pattern 125 is, therefore, formed beneath the gate pattern 200 and has a narrower width than the gate pattern 200.

Referring still to FIG. 4, the isotropic etching of the gate insulating layer recesses the exposed side wall of the gate insulating layer beyond the lower corner of the gate conductive layer pattern to form an undercut region beneath the lower gate pattern 130.

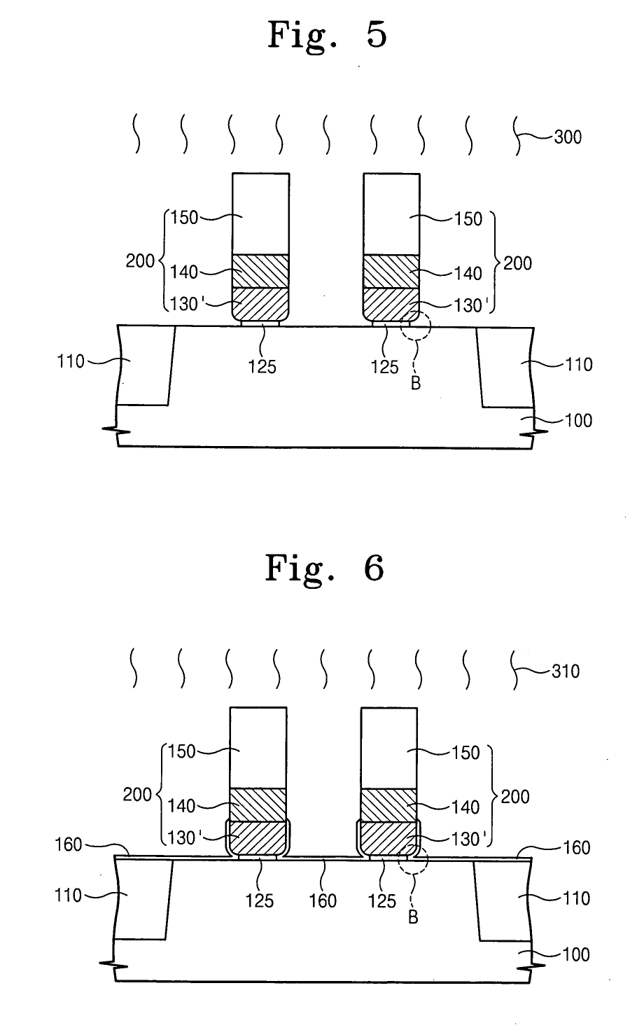

Referring to FIG. 5, the semiconductor substrate 100 including the gate insulating layer pattern 125 is treated using, for example, a hydrogen annealing process 300. The hydrogen annealing process 300 can be performed using a hydrogen (H₂) gas or hydrogen (H) atoms. In some embodiments according to the invention, the hydrogen annealing 300 uses H₂ gas or H atoms with an oxygen (O₂) gas, water vapor (H₂O), nitrogen (N₂) gas, Argon (Ar) gas and/or Helium (He) gas. In some embodiments according to the present invention, the hydrogen annealing process 300 is performed for about 5 through about 30 minutes at a temperature of about 650 to about 800° C. Other times and temperatures may be used. For example, the hydrogen annealing process 300 may be performed for about 30 minutes to about one hour at a temperature of about 600 to about 1100° C.

The hydrogen provided in the hydrogen annealing process 300 can transition the exposed silicon atoms (for example, at the side wall) to a stabler energy state to round off the lower corner of the lower gate pattern 130 located above the gate insulating layer pattern 125.

Referring to FIG. 6, after the hydrogen annealing process 300 is performed, a selective oxidation process 310 can be performed under a conditions to promote the selective oxidation of silicon. Accordingly, a silicon oxide layer 160 can be formed on an exposed surface of a lower gate pattern 130′ having the rounded corner. The oxidation process 310 may be performed using dry oxidation, wet oxidation, or low temperature radical oxidation. The oxidation process 310 may repair etching damage to the lower gate pattern 130′.

In accordance with some embodiments of the present invention, after the gate pattern 200 is formed, the oxidation process 310 may be performed without the hydrogen annealing process 300. In this case, as oxygen can penetrate the angular edge more effectively, the lower edge B of the lower gate pattern 130 may be additionally oxidized. Accordingly, the lower gate pattern 130 may have a rounded lower edge B. In accordance with still other embodiments of the present invention, the hydrogen annealing process 300 may be performed with the oxidation process 310.

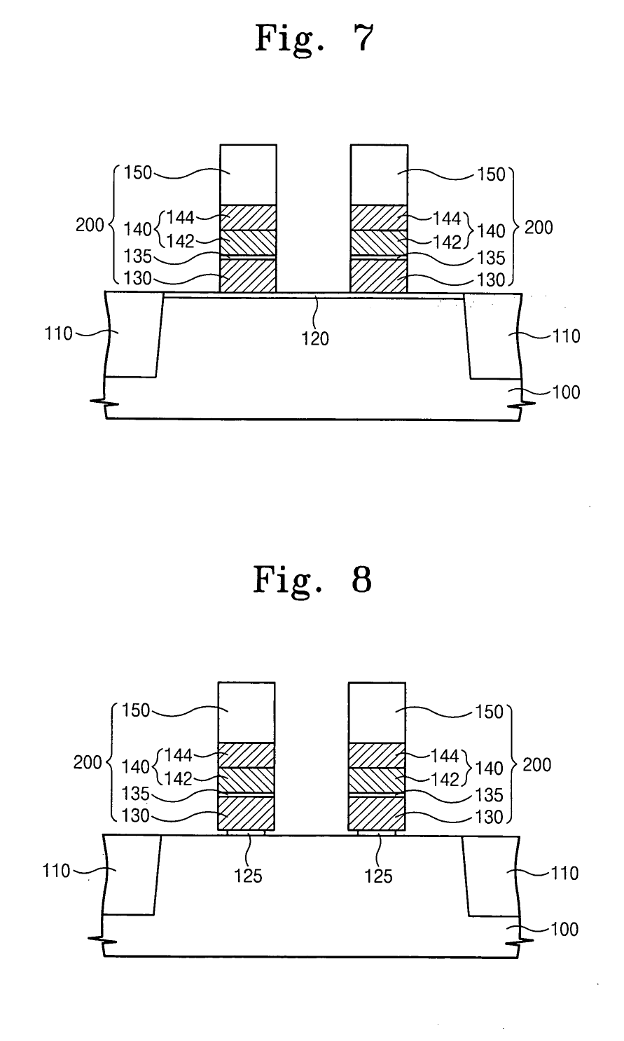

FIGS. 7 to 10 are cross-sectional views illustrating methods of forming gate patterns of a semiconductor device in accordance with some embodiments of the present invention, where, for example, floating gates of non-volatile memories may be formed. The structures shown in FIG. 7 can be formed as described above.

Referring to FIG. 7, before the upper gate conductive layer is formed, a step of forming a gate interlayer insulating layer on a resulting structure on which the lower gate conductive layer is formed may be further included. In addition, the upper gate conductive layer may be divided into a first upper gate layer and a second upper gate, layer, which are sequentially stacked.

The gate interlayer insulating layer is formed of a stacked structure including a silicon oxide layer, a silicon nitride layer and a silicon oxide layer. In some embodiments according to the invention, a high-k dielectric layer such as a hafnium oxide HfO₂ layer, an aluminum oxide Al₂O₃ layer, a zirconium oxide ZrO₂ layer, a tantalum oxide Ta₂O₅ layer, a titanium oxide TiO₂ layer, a lanthanum oxide La₂O₃ layer and a hafnium silicon oxide HfₓSi₁₋ₓO₂ layer may be used.

The capping layer, the second upper gate layer, the first upper gate layer, the gate interlayer insulating layer and the lower gate conductive layer are sequentially patterned to form a gate pattern 200 over the active region on top of the gate insulating layer 120. The gate pattern 200 includes a lower gate pattern 130, a gate interlayer insulating layer 135, a first upper gate pattern 142, a second upper gate pattern 144 and a capping pattern 150. The first upper gate pattern 142 and the second upper gate pattern 144 represent an upper gate pattern 140. In some embodiments according to the present invention, the lower gate pattern 130 and the second gate pattern 140 are formed using anisotropic etching using the capping pattern 150 as an etch mask.

Referring to FIG. 8, the gate insulating layer 120 is recessed by isotropically etching to form an undercut region between the lower gate pattern 130 and the semiconductor substrate 100. The etching solution used can be capable of selectively etching the gate insulating layer 120 without etching the gate pattern 200, the device isolation layer 110 and the semiconductor substrate 100. Accordingly, the gate insulating layer 120 and the gate interlayer insulating layer 135 may be formed of a different materials.

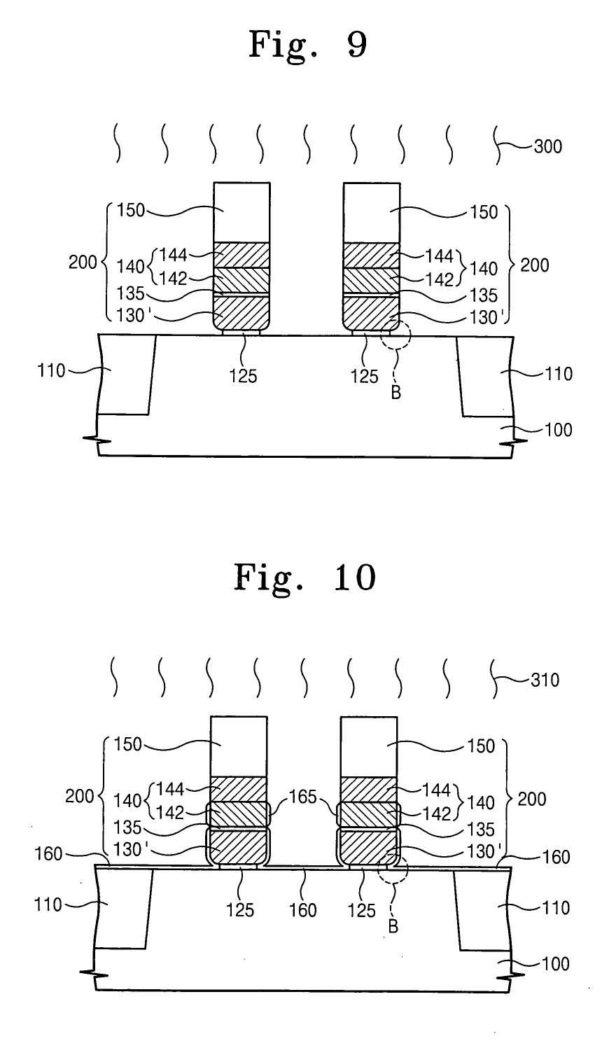

Referring to FIGS. 9 and 10, the semiconductor substrate 100 (including the gate insulating layer pattern 125) is treated using, for example, a hydrogen annealing process 300 illustrated in FIG. 5. Accordingly, an angular lower edge (or corner) of the lower gate pattern 130 can be rounded.

A selective oxidation process 310 can be performed under process conditions to promote the selective oxidation of silicon with respect to a resultant structure on which a lower gate pattern 130 having the rounded corner. Accordingly, a silicon oxide layer 160 is formed on an exposed surface of a lower gate pattern 130′ having the rounded corner. If the first upper gate pattern 142 is formed of polycrystalline silicon, a silicon oxide layer 165 may be formed at sidewalls of the first upper gate pattern 142.

mbodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method for forming a gate pattern of a semiconductor device comprising:
isotropically etching a gate insulating layer located between a gate conductive layer pattern and a substrate to recess an exposed side wall of the gate insulating layer pattern beyond a lower corner of the gate conductive layer pattern to form an undercut region; and
treating the gate conductive layer pattern to round off the lower corner.

2. A method according to claim I wherein treating the semiconductor comprises annealing the gate conductive layer pattern using a process gas comprising hydrogen.

3. A method according to claim 2 wherein annealing comprises annealing using hydrogen H₂ gas and/or hydrogen H atoms, or using H₂ gas and/or H atoms with O₂ gas, H₂O, N₂ gas, Ar gas and/or He gas.

4. A method according to claim 2 further comprising:
forming a silicon oxide layer on a side wall of the gate conductive layer pattern.

5. A method according to claim 4 wherein forming a silicon oxide layer comprises dry oxidation, wet oxidation or a low temperature radical oxidation.

6. A method according to claim 1 wherein treating comprises oxidizing to forming a silicon oxide layer on a side wall of the gate conductive layer pattern.

7. A method according to claim 6 wherein oxidizing comprises oxidizing and annealing using a process gas comprising H₂ gas and/or H atoms, or H₂ gas and/or H atoms with O₂ gas, H₂O, N₂ gas, Ar gas and/or He gas.

8. A method according to claim 1 wherein the gate conductive layer pattern comprises polycrystalline silicon.

9. A method according to claim 1 further comprising:
wet-etching the gate insulating layer using the gate conductive layer pattern as an etch mask, wherein the wet-etching is performed using an etching solution having an etch selectivity with respect to the gate conductive layer pattern.

10. A method according to claim 1 wherein the gate insulating layer comprises a silicon oxide SiO₂ layer, a hafnium oxide HfO₂ layer, an aluminum oxide Al₂O₃ layer, a zirconium oxide ZrO₂ layer, a tantalum oxide Ta₂O₅ layer, a titanium oxide TiO₂ layer, a lanthanum oxide La₂O₃ layer and/or a hafnium silicon oxide HfₓSi₁₋ₓO₂ layer.

11. A method of forming a gate pattern of a semiconductor device comprising:
forming a gate insulating layer on a semiconductor substrate;
forming a gate pattern exposing a top surface of a predetermined region of the gate insulating layer, the gate pattern comprising a lower gate pattern, a gate interlayer insulating layer pattern and an upper gate pattern;
isotropically etching the gate insulating layer between to recess an exposed side wall of the gate insulating layer beyond a lower corner of the lower gate pattern to form an undercut region therebeneath; and
treating the gate conductive layer pattern to round off the lower corner.

12. A method according to claim 11 wherein the lower gate pattern comprises polycrystalline silicon, and the upper gate pattern comprises polycrystalline silicon and a metal conductive layer sequentially stacked.

13. A method according to claim 11 wherein forming the gate insulating layer pattern comprises wet-etching the gate insulating layer using the gate pattern as an etch mask, wherein the wet-etching is performed using an etching solution that is selective with respect to the gate pattern.

14. A method according to claim 11 wherein treating comprises annealing the lower corner of the gate pattern using a process gas.

15. A method according to claim 14, wherein the process gas comprises H₂ gas and/or H atoms or H₂ gas and/or H atoms with O₂ gas, H₂O, N₂ gas, Ar gas and/or He gas.

16. A method according to claim 14 further comprising:
forming a silicon oxide layer on an exposed surface of the lower gate pattern.

17. A method according to claim 16 wherein forming a silicon oxide layer dry oxidation, a wet oxidation or a low temperature radical oxidation.

18. A method according to claim 11 wherein treating comprises oxidizing to form a silicon oxide layer on an exposed surface of the gate conductive layer pattern.

19. A method according to claim 18 further comprising:
annealing using a process gas comprising H₂ gas or H atoms, or H₂ gas or H atoms with O₂ gas, H₂O, N₂ gas, Ar gas and He gas.

20. A method of forming a gate pattern of a semiconductor device comprising forming a gate insulating layer on a semiconductor substrate;
forming a gate pattern exposing a top surface of a predetermined region of the gate insulating layer, the gate pattern comprising a lower gate pattern, a gate interlayer insulating layer pattern, and an upper gate pattern;
isotropically etching the gate insulating layer to recess an exposed side wall of the gate insulating layer beyond a lower corner of the lower gate pattern to form an undercut region therebeneath;
treating the gate pattern to round off the lower corner of the lower gate pattern; and
oxidizing a side wall of the lower gate pattern, a portion of undercut region, and a side wall of the gate interlayer insulating layer pattern; and
oxidizing a side wall of the upper gate pattern above the gate interlayer insulating layer pattern.
